(19) United States
(12) Patent Application Publication
(10) Pub. No.: US 2026/0056238 A1
(43) Pub. Date: Feb. 26, 2026

(54) METHOD AND DEVICE FOR DETECTING ELECTRIC FIELD

(71) Applicants: PANASONIC CONNECT CO., LTD., Fukuoka (JP); NATIONAL UNIVERSITY CORPORATION KANAZAWA UNIVERSITY, Ishikawa (JP)

(72) Inventors: Shinichi TANIMOTO, Kyoto (JP); Shinkuro FUJINO, Kyoto (JP); Akihiro TATSUTA, Kyoto (JP); Satoshi YAGITANI, Ishikawa (JP); Kensuke SHIMIZU, Ishikawa (JP); Shinjiro NISHI, Ishikawa (JP)

(73) Assignees: PANASONIC CONNECT CO., LTD., Fukuoka (JP); NATIONAL UNIVERSITY CORPORATION KANAZAWA UNIVERSITY, Ishikawa (JP)

(21) Appl. No.: 19/129,882

(22) PCT Filed: Sep. 28, 2023
(86) PCT No.: PCT/JP2023/035550

§ 371 Date: May 14, 2025

(30) Foreign Application Priority Data
Nov. 16, 2022 (JP) 2022-183563

(51) Int. Cl. G01R 29/08; G01R 29/10

(52) U.S. Cl. CPC G01R 29/0878; G01R 29/105

(57) ABSTRACT

An antenna device includes a ground conductor, a first conductor disposed on a plane formed by a first conductor layer parallel to the ground conductor, a first conductor rod electrically connecting the first conductor and the ground conductor, a plurality of first terminal rods extending from the first conductor to a back surface of the ground conductor, a second conductor disposed above the first conductor and disposed on a plane formed by a second conductor layer parallel to the ground conductor, and a plurality of second terminal rods extending from the second conductor to the back surface of the ground conductor.

### TECHNICAL FIELD

The present disclosure relates to an electric field detection method and device.

### BACKGROUND ART

A technique called an electromagnetic band gap (EBG) structure using a metamaterial called a left-handed medium or a negative refractive index medium is known as a technique for preventing strength (for example, an electric field) of electromagnetic noise generated from a printed circuit board or the like incorporated in an electronic device housing. The EGB structure has a periodic structure having a frequency band (band gap) that blocks radio waves.

Patent Literature 1 discloses an electromagnetic coupling control device to which the above EGB structure is applied. The electromagnetic coupling control device includes: a ground conductor; a plurality of first conductor patches disposed on a plane formed by a first conductor layer parallel to the ground conductor; a first conductor rod connecting each of the plurality of first conductor patches to the ground conductor; a plurality of second conductor patches disposed on a plane formed by a second conductor layer parallel to the ground conductor and located between the ground conductor and the first conductor layer and disposed for each of the plurality of first conductor patches; and a second conductor rod connecting each of the plurality of second conductor patches to the corresponding first conductor patch.

### CITATION LIST

### Patent Literature

Patent Literature 1: WO2021/255811

### SUMMARY OF INVENTION

### Technical Problem

As one of pre-shipment inspections of an electronic device, there is a test as to whether an electromagnetic compatibility (EMC) standard is satisfied in an environment in which the electronic device is installed, the EMC standard indicating that the electronic device functions in the environment without causing an unacceptable interference (for example, radio wave noise) to other electronic devices. This test is performed in an anechoic chamber so as not to be affected by the surrounding radio wave environment. In the test in the anechoic chamber, it is necessary to confirm that the EMC standard is satisfied in a desired frequency band (for example, a plurality of frequencies) according to the electronic device. When the EMC standard is not satisfied in this test, measures against radio wave noise are required, but there is a problem that it is difficult to shorten a time required for the entire verification for specifying a noise generation source. Also in Patent Literature 1, a technical solution focusing on this problem is not presented.

The present disclosure has been made in view of the circumstances of the related art described above, and an object of the present disclosure is to provide an electric field detection method and device that can cope with a wider frequency band suitable for absorbing radio wave noise and support shortening of a time required for verification for specifying a radio wave noise generation source.

### Solution to Problem

The present disclosure provides an antenna device including: a ground conductor; a first conductor disposed on a plane formed by a first conductor layer parallel to the ground conductor; a first conductor rod electrically connecting the first conductor and the ground conductor; a plurality of first terminal rods extending from the first conductor to a back surface of the ground conductor; a second conductor disposed above the first conductor and disposed on a plane formed by a second conductor layer parallel to the ground conductor; and a plurality of second terminal rods extending from the second conductor to the back surface of the ground conductor.

### Advantageous Effects of Invention

According to the present disclosure, it is possible to cope with a wider frequency band suitable for absorbing radio wave noise, making it possible to specify a generation source of radio wave noise and improve efficiency of noise countermeasures.

### BRIEF DESCRIPTION OF DRAWINGS

FIG. 1 is a diagram illustrating noise analysis in an anechoic chamber using an electric field detection device according to the present embodiment;

FIG. 2 is a diagram schematically illustrating an example of a side cross section cut along a plane parallel to a thickness direction of a sensor substrate;

FIG. 3 is a diagram illustrating an example of two types of periodic (loop) structures of the sensor substrate;

FIG. 4 is a diagram illustrating an example of an equivalent circuit corresponding to a basic structure that is the basis of the two types of periodic structures in FIG. 3;

FIG. 5 is a plan view illustrating an arrangement example of first conductors and second conductors obliquely arranged with respect to a dielectric substrate;

FIG. 6 is a plan view illustrating an arrangement example of resistors for radio wave absorption connected between the first conductors and between the second conductors in FIG. 5;

FIG. 7 is a diagram illustrating a reception level characteristic example in which a structure of the sensor substrate according to the present embodiment and a structure of an antenna device according to a comparative example are compared; and

FIG. 8 is a diagram comparatively illustrating each reception level characteristic example when a distance t between the first conductor and the second conductor in the sensor substrate according to the present embodiment is variable.

### DESCRIPTION OF EMBODIMENTS

Hereinafter, an embodiment specifically disclosing an electric field detection method and device according to the present disclosure will be described in detail with reference to the drawings as appropriate. However, unnecessarily detailed descriptions may be omitted. For example, the detailed descriptions of well-known matters and the redundant description of substantially the same configuration may be omitted. This is to avoid unnecessary redundancy of the following descriptions and to facilitate understanding of those skilled in the art. The accompanying drawings and the following description are provided for those skilled in the art to fully understand the present disclosure, and are not intended to limit the subject matter described in the claims.

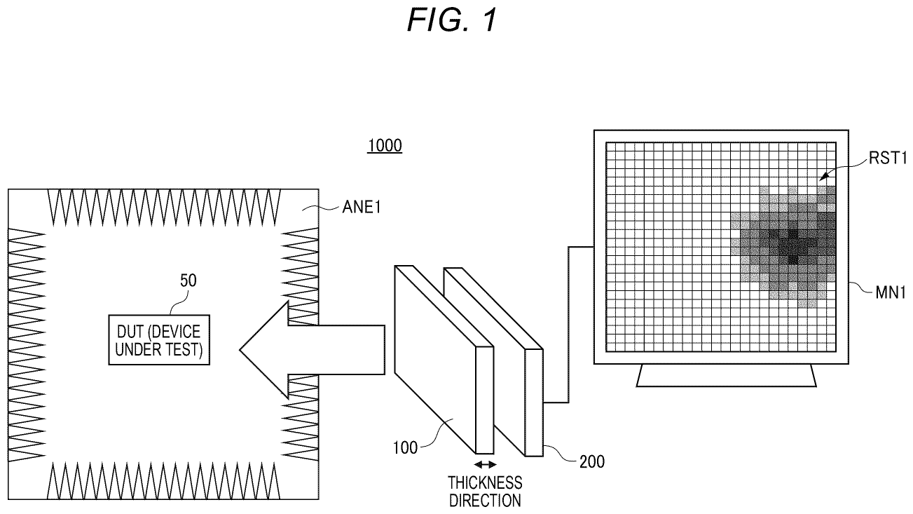

First, verification of radio wave noise using an electric field detection device 1000 according to the present embodiment will be described with reference to FIG. 1. FIG. 1 is a diagram illustrating noise analysis in an anechoic chamber ANE1 using the electric field detection device 1000 according to the present embodiment. The electric field detection device 1000 includes at least a sensor substrate 100 as an example of an antenna device and a display PC 200 for displaying a measurement result of radio wave noise or electromagnetic wave noise (hereinafter, collectively referred to as “radio wave noise”) from a device under test (DUT) 50. Although not illustrated in FIG. 1, a control circuit (not illustrated) of the sensor substrate 100 is electrically connected to the sensor substrate 100, and the sensor substrate 100 and the display PC 200 are connected so as to be capable of inputting and outputting signals via a coaxial cable (not illustrated), a real-time spectrum analyzer (not illustrated), and a universal serial bus (USB) cable (not illustrated). The electric field detection device 1000 may further include a monitor MN1 in addition to the sensor substrate 100 and the display PC 200. The electric field detection device 1000 is disposed in the anechoic chamber ANE1 while the radio wave noise from the device under test 50 is measured.

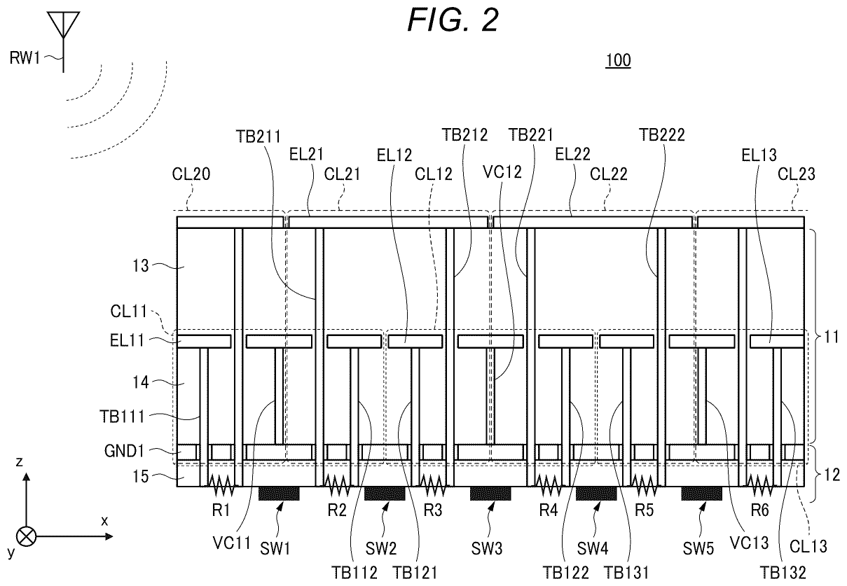

The device under test 50 is disposed in the anechoic chamber ANE1 and is, for example, an object to be measured of radio wave noise which is one of pre-shipment inspections, and is specifically an electronic device. The electronic device referred to here is not particularly limited, and examples thereof include a PC, a tablet terminal, a smartphone, and a television receiver. The device under test 50 has a noise source of radio wave noise (in other words, a radio wave source RW1 (see FIG. 2)). A frequency band of the radio wave noise is not particularly limited, but is, for example, a wide range of 800 MHz to 1.5 GHz used in the frequency of a mobile phone.

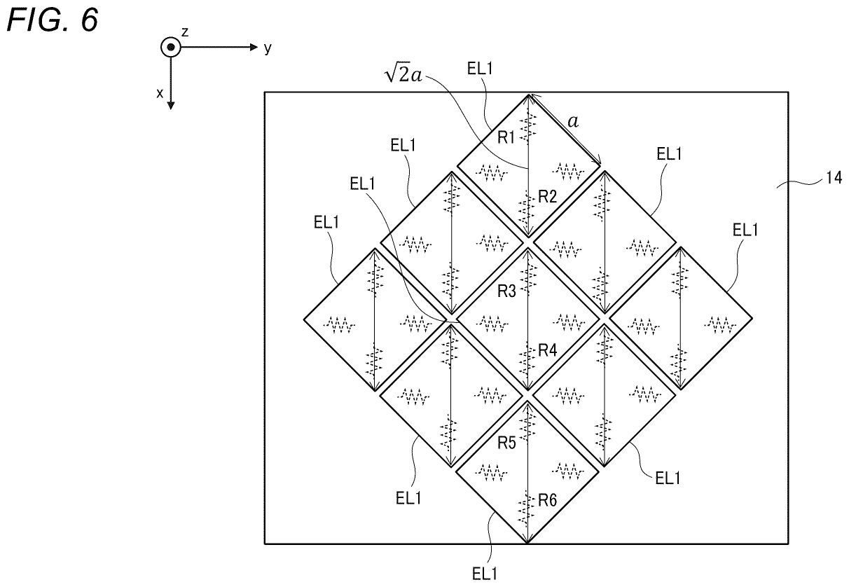

The sensor substrate 100 is an example of an antenna device for measuring radio wave noise from the device under test 50, and is disposed in the vicinity of the device under test 50 in the anechoic chamber ANE1. In the sensor substrate 100, a plurality of observation points for horizontal polarization detection (see a resistor illustrated in FIG. 6) and a plurality of observation points for vertical polarization detection (see a resistor illustrated in FIG. 6) are two-dimensionally disposed, and an RF switch element (see FIG. 2) is provided for each observation point. The sensor substrate 100 operates based on a control signal from the control circuit (see the above), absorbs radio wave noise radiated from the device under test 50 disposed in the anechoic chamber ANE1 by making radio wave noise incident thereon, for example, and acquires a signal of the absorbed radio wave noise. More specifically, the sensor substrate 100 controls each of the RF switch elements of the sensor substrate 100 by a microcomputer (not illustrated) mounted on the control circuit (not illustrated), sequentially selects the RF signal of the radio wave noise absorbed by the observation point (the resistor) from the corresponding RF switch element, and outputs the RF signal to the real-time spectrum analyzer (not illustrated) via a coaxial cable (not illustrated). The real-time spectrum analyzer (not illustrated) samples the input RF signal and transfers it to the display PC 200 via a USB cable (not illustrated). A specific configuration for incidence and absorption of radio wave noise of the sensor substrate 100 will be described later with reference to FIG. 2.

The display PC 200 collects a sampling result of the signal of the radio wave noise from the device under test 50 absorbed by the sensor substrate 100, calculates an electric field strength at each observation point, and generates a measurement result mapping image RST1 which is an electric field strength distribution two-dimensionally indicating the electric field strength at each observation point. The display PC 200 includes various hardware (for example, a processor such as a central processing unit (CPU), a memory including a random access memory (RAM) and a read only memory (ROM), a hard disk drive, or a solid state drive) included in a normal personal computer. Each time the display PC 200 generates the measurement result mapping image RST1, the display PC 200 outputs the generated measurement result mapping image RST1 to the monitor MN1 for updating and display it.

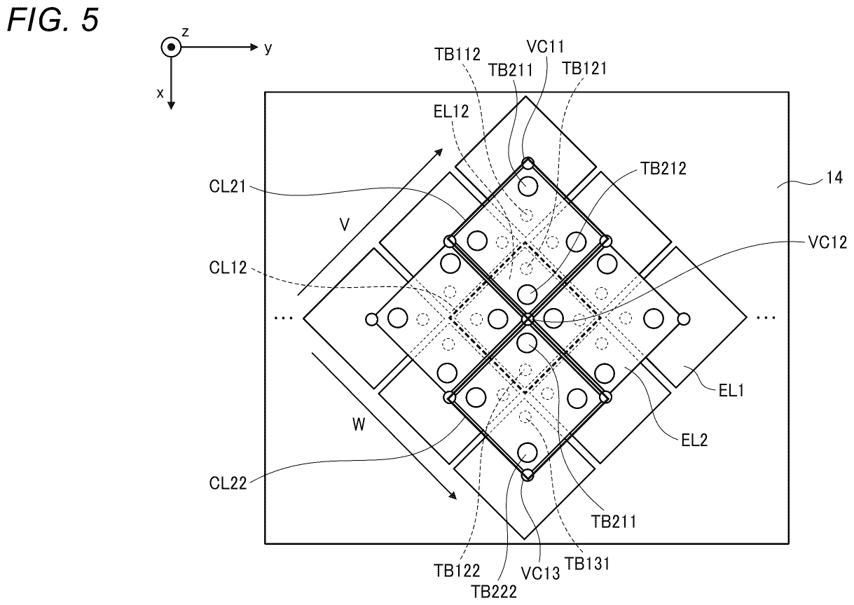

Next, a specific structure example in the thickness direction (see FIG. 1) of the sensor substrate 100 according to the present embodiment will be described with reference to FIG. 2. FIG. 2 is a diagram schematically illustrating an example of a side cross section cut along a plane parallel to the thickness direction of the sensor substrate 100. In the present specification, an x-axis, a y-axis, and a z-axis are defined as directions illustrated in FIG. 2. The z-axis indicates the thickness direction of the sensor substrate 100 (see FIG. 1). The y-axis is orthogonal to the z-axis and the x-axis, and is parallel to a longitudinal direction of a ground conductor GND1, for example (see FIG. 5). The x-axis is orthogonal to the z-axis and the y-axis, and is, for example, parallel to a lateral direction of the ground conductor GND1 (see FIG. 5).

The sensor substrate 100 includes a radio wave absorber 11 and a signal output unit 12.

The radio wave absorber 11 has a periodic structure for absorbing radio wave noise from the radio wave source RW1 incident on the sensor substrate 100. Specifically, the radio wave absorber 11 includes the ground conductor GND1, a plurality of first unit cells CL11, CL12, CL13, . . . , and a plurality of second unit cells CL20, CL21, CL22, CL23, . . . .

The signal output unit 12 includes a plurality of acquisition circuits that acquire the signal of the radio wave noise absorbed by the radio wave absorber 11. The acquisition circuit includes a resistor and an RF switch element. Specifically, the signal output unit 12 includes a plurality of resistors R1, R2, R3, R4, R5, R6, . . . and RF switch elements SW1, SW2, SW3, SW4, SW5, . . . connected to the plurality of resistors.

First, the radio wave absorber 11 will be described.

The ground conductor GND1 is disposed parallel to an xy plane, and is formed in, for example, a rectangular shape. Specifically, the ground conductor GND1 is a flat conductor such as a conductor plane formed on one surface (for example, a front surface) of a substrate such as a printed circuit board.

Each of the plurality of first unit cells CL11, CL12, CL13, . . . is disposed on one surface (for example, see the above surface) of the ground conductor GND1 in a direction (the thickness direction) orthogonal to a plane formed by the ground conductor GND1. Specifically, the plurality of first unit cells CL11, CL12, CL13, . . . are arranged at equal intervals in two different directions (for example, a direction of an arrow W and a direction of an arrow V illustrated in FIG. 5) in the plane (for example, a plane parallel to the xy plane illustrated in FIG. 5) formed by the ground conductor GND1. Since the first unit cells have the same structure, the first unit cell CL12 will be described here as an example. In other words, the description of the first unit cell CL12 is similarly applicable to other first unit cells (for example, the first unit cells CL11, CL13, . . . ).

The first unit cell CL12 includes a first conductor EL12, a first conductor rod VC12, and a plurality of (for example, two) first terminal rods TB121 and TB122. The first unit cell CL11 includes a first conductor EL11, a first conductor rod VC11, and a plurality of (for example, two) first terminal rods TB111 and TB112. Similarly, the first unit cell CL13 includes a first conductor EL13, a first conductor rod VC13, and a plurality of (for example, two) first terminal rods TB131 and TB132.

The first conductor EL12 is a flat (in other words, rectangular) conductor disposed in a first conductor layer (for example, a dielectric substrate 14, the same applies hereinafter) parallel to the ground conductor GND1. Therefore, in the sensor substrate 100 according to the present embodiment, a plurality of first conductors constituting the first unit cell are arranged at equal intervals in each of two different directions in the plane formed by the first conductor layer. Specifically, the plurality of first conductors are arranged at equal intervals in the direction of the arrow W illustrated in FIG. 5 and the direction of the arrow V orthogonal to the direction of the arrow W in the plane formed by the first conductor layer.

The term “parallel” is not limited to strictly parallel and may include substantially parallel, but is preferably strictly parallel. In the following description, “parallel” includes “substantially parallel”. The equal intervals are not limited to strictly equal intervals and may include substantially equal intervals, but are preferably strictly equal intervals. In the following description, the equal intervals include substantially equal intervals.

The shape of the first conductor constituting the first unit cell is, for example, a square in a plan view (see FIG. 5), but is not limited to a square, and may be, for example, a polygon or a circle. Specifically, the shape of the first conductor may be any shape such as a quadrangle such as a square, a rectangle, a rhombus, or a parallelogram, a triangle such as a regular triangle, an isosceles triangle, or a right triangle, a polygon such as a regular polygon having five or more vertices, or a circle such as a perfect circle or an ellipse in a plan view. A length (thickness) of the first conductor in the thickness direction is any, but is preferably smaller than a wavelength of the frequency band of the radio wave noise absorbed by the sensor substrate 100.

The first conductor rod VC12 is a rod-shaped conductor that electrically connects (conducts) the first conductor EL12 and the ground conductor GND1 disposed on the dielectric substrate 14, and may be referred to as a via conductor. The first conductor rod VC12 is inserted into a hole provided to penetrate the dielectric substrate 14 for the first conductor rod VC12, and conducts between the first conductor EL12 and the ground conductor GND1. The first conductor rod VC12 is a columnar rod, but is not limited to the columnar rod, and may be a cylindrical rod or a prismatic rod. Further, the shape of the first conductor rod VC12 is not limited to a columnar shape, a cylindrical shape, or a prismatic shape, and may be, for example, a frustum shape.

Each of the first terminal rods TB121 and TB122 is a rod-shaped conductor extending from the first conductor EL12 to a back surface of the ground conductor GND1 (that is, a surface opposite to the above surface, the same applies hereinafter) or beyond the back surface. Each of the first terminal rods TB121 and TB122 is inserted into a through hole provided to penetrate both the dielectric substrate 14 of the radio wave absorber 11 and a dielectric substrate 15 of the signal output unit 12 for the first terminal rod. A dielectric substrate 13, the dielectric substrate 14, and the dielectric substrate 15 may be integrally provided or may be separately provided. One end side of the first terminal rod TB121 is connected to the first conductor EL12, and the other end side of the first terminal rod TB121 is connected to one end side of the resistor R3 of the signal output unit 12. The other end side of the resistor R3 is connected to the other end side of a second terminal rod TB212 opposite to one end side thereof connected to a second conductor EL21, the second terminal rod TB212 constituting a second unit cell CL21. One end side of the first terminal rod TB122 is connected to the first conductor EL12, and the other end side of the first terminal rod TB122 is connected to the other end side of the resistor R4 of the signal output unit 12. One end side of the resistor R4 is connected to the other end side of a second terminal rod TB221 opposite to one end side thereof connected to a second conductor EL22, the second terminal rod TB221 constituting a second unit cell CL22.

Each of the plurality of second unit cells CL20, CL21, CL22, CL23, . . . is disposed on one surface (for example, see the above surface) of the ground conductor GND1 in the direction (the thickness direction) orthogonal to the plane formed by the ground conductor GND1. Specifically, the plurality of second unit cells CL20, CL21, CL22, CL23, . . . are arranged at equal intervals in two different directions (for example, the direction of the arrow W and the direction of the arrow V illustrated in FIG. 5) in the plane (for example, the plane parallel to the xy plane illustrated in FIG. 5) formed by the ground conductor GND1. Since the second unit cells have the same structure, the second unit cell CL21 will be described here as an example. In other words, the description of the second unit cell CL21 is similarly applicable to other second unit cells (for example, the second unit cells CL20, CL22, CL23, . . . ).

The second unit cell CL21 includes the second conductor EL21 and a plurality of (for example, two) second terminal rods TB211 and TB212. The second unit cell CL22 includes the second conductor EL22 and a plurality of (for example, two) second terminal rods TB221 and TB222.

The second conductor EL21 is a flat (in other words, rectangular) conductor disposed in a second conductor layer (for example, the dielectric substrate 13; the same applies hereinafter) parallel to the ground conductor GND1. Therefore, in the sensor substrate 100 according to the present embodiment, a plurality of second conductors constituting the second unit cell are arranged at equal intervals in each of two different directions in the plane formed by the second conductor layer. Specifically, the plurality of second conductors are arranged at equal intervals in the direction of the arrow W illustrated in FIG. 5 and the direction of the arrow V orthogonal to the direction of the arrow W in the plane formed by the second conductor layer.

The shape of the second conductor constituting the second unit cell is, for example, a square in a plan view (see FIG. 5), but is not limited to a square, and may be, for example, a polygon or a circle. Specifically, the shape of the second conductor may be any shape such as a quadrangle such as a square, a rectangle, a rhombus, or a parallelogram, a triangle such as a regular triangle, an isosceles triangle, or a right triangle, a polygon such as a regular polygon having five or more vertices, or a circle such as a perfect circle or an ellipse in a plan view. A length (thickness) of the second conductor in the thickness direction is any, but is preferably smaller than the wavelength of the frequency band of the radio wave noise absorbed by the sensor substrate 100, for example.

Each of the second terminal rods TB211 and TB212 is a rod-shaped conductor extending from the second conductor EL21 to the back surface of the ground conductor GND1 or beyond the back surface. Each of the second terminal rods TB211 and TB212 is inserted into a through hole provided to penetrate both the dielectric substrate 14 of the radio wave absorber 11 and the dielectric substrate 15 of the signal output unit 12 for the second terminal rod. One end side of the second terminal rod TB211 is connected to the second conductor EL21, and the other end side of the second terminal rod TB211 is connected to one end side of the resistor R2 of the signal output unit 12. The other end side of the resistor R2 is connected to the other end side of the first terminal rod TB112 opposite to the one end side thereof connected to the first conductor EL11, the first terminal rod TB112 constituting the first unit cell CL11. One end side of the second terminal rod TB212 is connected to the second conductor EL21, and the other end side of the second terminal rod TB212 is connected to the other end side of the resistor R3 of the signal output unit 12. The other end side of the resistor R3 is connected to the other end side of the first terminal rod TB121 opposite to the one end side thereof connected to the first conductor EL12, the first terminal rod TB121 constituting the first unit cell CL12.

In the first unit cell and the second unit cell, conduction is not established between the second terminal rod of the second unit cell and the first conductor of the first unit cell. As exemplified with reference to FIG. 2, conduction is not established between the second terminal rod TB211 and the first conductor EL11, between the second terminal rod TB212 and the first conductor EL12, between the second terminal rod TB221 and the first conductor EL12, and between the second terminal rod TB222 and the first conductor EL13.

In the first unit cell, the second unit cell, and the ground conductor GND1, conduction is not established between the first terminal rod and the ground conductor GND1 and between the second terminal rod and the ground conductor GND1, respectively. As exemplified with reference to FIG. 2, conduction is not established between the first terminal rod TB111 and the ground conductor GND1, between the second terminal rod TB211 and the ground conductor GND1, between the first terminal rod TB112 and the ground conductor GND1, between the first terminal rod TB121 and the ground conductor GND1, between the second terminal rod TB212 and the ground conductor GND1, between the second terminal rod TB221 and the ground conductor GND1, between the first terminal rod TB122 and the ground conductor GND1, between the first terminal rod TB131 and the ground conductor GND1, between the second terminal rod TB222 and the ground conductor GND1, and between the first terminal rod TB132 and the ground conductor GND1.

The plurality of first unit cells and the plurality of second unit cells disposed on the surface of the radio wave absorber 11 are arranged in a matrix at intervals sufficiently shorter than the wavelength of the radio wave emitted (radiated) from the radio wave source RW1. Vertical and horizontal lengths (sizes) of each of the plurality of first unit cells and the plurality of second unit cells disposed on the surface of the radio wave absorber 11 are sufficiently shorter than the wavelength of the radio wave emitted (radiated) from the radio wave source RW1. A frequency of the radio wave emitted from the radio wave source RW1 is, for example, a frequency between 800 MHz to 1.5 GHz. The wavelength of the radio wave having a frequency of 800 MHz is 37.5 cm. The wavelength of the radio wave having a frequency of 1.5 GHz is 20.0 cm. An interval between the first unit cell CL11 and the first unit cell CL12 and an interval between the second unit cell CL21 and the second unit cell CL22 are, for example, 1 millimeter. The vertical and horizontal lengths of the first unit cell and the second unit cell are, for example, 20 millimeters.

The sensor substrate 100 according to the present embodiment forms the first EBG structure by the ground conductor GND1 and the plurality of first unit cells CL11, CL12, CL13, . . . . With the first EBG structure, the sensor substrate 100 can absorb and prevent radio wave noise in a first frequency band (for example, 800 MHz band) of radio wave noise radiated from the radio wave source RW1 (for example, a substrate built in the device under test 50) of the device under test 50 (see FIG. 1). Since the technical principle of preventing radio wave noise in a predetermined frequency band by the EBG structure is well known, the description thereof is omitted here.

In the sensor substrate 100 according to the present embodiment, the ground conductor GND1 and the plurality of second unit cells CL20, CL21, CL22, CL23, . . . form a second EBG structure. With the second EBG structure, the sensor substrate 100 can absorb and prevent radio wave noise in a second frequency band (for example, 1.5 GHz band) of radio wave noise radiated from the radio wave source RW1 (for example, a substrate built in the device under test 50) of the device under test 50 (see FIG. 1).

Next, the signal output unit 12 will be described.

The resistors R1, R2, R3, R4, R5, R6, . . . each constitute an acquisition circuit in the signal output unit 12. Each resistor consumes (absorbs) electric power (energy) of radio wave noise absorbed in the first unit cell or the second unit cell connected to the resistor. The value of each resistor is, for example, 377 ohms, which is a wave impedance in a free space.

Each of the RF switch elements SW1, SW2, SW3, SW4, SW5, . . . constitutes an acquisition circuit in the signal output unit 12. The RF switch element is provided in one-to-one correspondence with the resistor. The RF switch elements SW1, SW2, SW3, SW4, SW5, . . . output signals of the radio wave noise consumed (absorbed) by the corresponding resistors to a real-time spectrum analyzer (not illustrated) connected to the sensor substrate 100 by a coaxial cable (not illustrated).

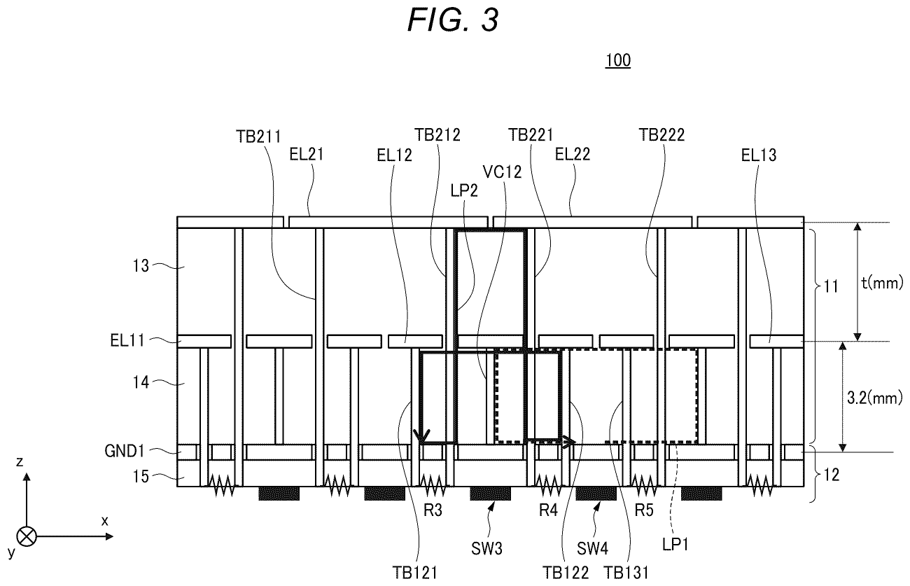

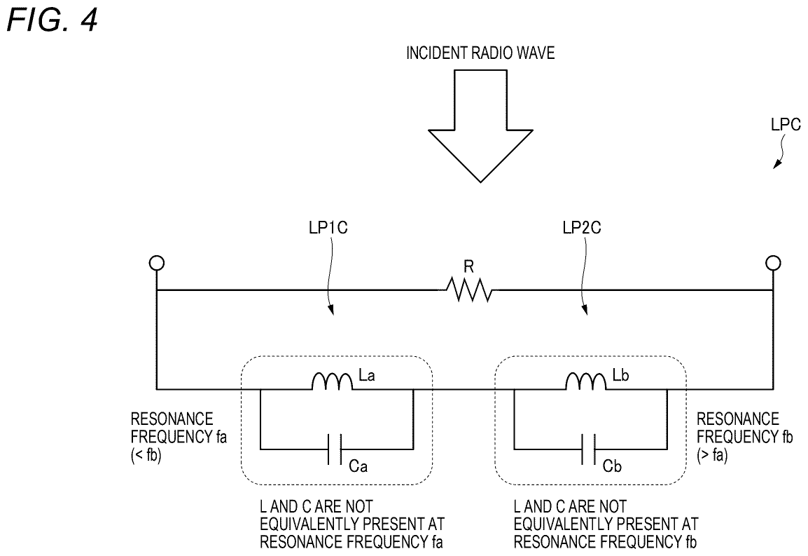

Next, two types of periodic EBG structures of the sensor substrate 100 according to the present embodiment will be described with reference to FIGS. 3, 4, 5, and 6. FIG. 3 is a diagram illustrating an example of two types of periodic (loop) structures of the sensor substrate 100. FIG. 4 is a diagram illustrating an example of an equivalent circuit corresponding to a basic structure that is the basis of two types of periodic structures in FIG. 3. FIG. 5 is a plan view illustrating an arrangement example of first conductors EL1 and second conductors EL2 obliquely arranged with respect to the dielectric substrate 14. FIG. 6 is a plan view illustrating an arrangement example of the resistors R1, R2, R3, R4, R5, R6, . . . for radio wave absorption connected between the first conductors EL1 and between the second conductors EL2 in FIG. 5.

In the description of FIGS. 3, 5 and 6, the same components as those in FIG. 2 are denoted by the same reference numerals, the description thereof will be simplified or omitted, and only the differences will be described.

The sensor substrate 100 according to the present embodiment has two types of periodic EBG structures. The basic structure (that is, a basic portion of the periodic structure) that is the basis of the first EBG structure is formed by the ground conductor GND1 and between the first unit cell CL12 and the second unit cell CL13, as indicated by a loop LP1 illustrated in FIG. 3. An equivalent circuit LP1C (see FIG. 4) indicating the first EBG structure is equivalently formed by the first unit cell CL12 including the first conductor EL12, the first unit cell CL13 including the first conductor EL13, and the ground conductor GND1. The length (height) from the ground conductor GND1 to the first unit cells CL12 and CL13 is, for example, 3.2 mm.

The basic structure (that is, a basic portion of the periodic structure) that is the basis of the second EBG structure is formed by the ground conductor GND1 and between the second unit cell CL21 and the second unit cell CL22, as illustrated in a loop LP2 illustrated in FIG. 3. An equivalent circuit LP2C (see FIG. 4) indicating the second EBG structure is equivalently formed by the second unit cell CL21 including the second conductor EL21, the second unit cell CL22 including the second conductor EL22, and the ground conductor GND1.

As illustrated in FIG. 4, the sensor substrate 100 according to the present embodiment repeatedly and periodically includes an equivalent circuit LPC in which the equivalent circuit LP1C illustrating the first EBG structure that absorbs incident radio waves and the equivalent circuit LP2C illustrating the second EBG structure that absorbs incident radio waves are connected in series, and a resistor R is provided in parallel with a series circuit of the equivalent circuits LP1C and LP2C. The resistor R may also include impedance components based on a resistance component, an inductance component, and a capacitance component present in a path of the loop LP1 and the loop LP2 in addition to the resistor R4 for radio wave absorption.

The equivalent circuit LP1C constitutes a parallel resonance circuit in which an inductance La and a capacitance Ca are connected in parallel. In the equivalent circuit LP1C, at a resonance frequency fa (for example, 800 MHz band), an impedance component due to the inductance La and the capacitance Ca is infinite, and it can be considered that there is no impedance of the other equivalent circuit LP2C connected in series, so that the impedance of the equivalent circuit LPC is uniquely determined by the resistor R and matches a wave impedance in a free space. That is, the sensor substrate 100 can easily and efficiently absorb the radio wave noise of the resonance frequency fa (for example, 800 MHz band).

The equivalent circuit LP2C constitutes a parallel resonance circuit in which an inductance Lb and a capacitance Cb are connected in parallel. In the equivalent circuit LP2C, at a resonance frequency fb (for example, 1.5 GHz band), an impedance component due to the inductance Lb and the capacitance Cb is infinite, and it can be considered that there is no impedance of the other equivalent circuit LP1C connected in series, so that the impedance of the equivalent circuit LPC is uniquely determined by the resistor R and matches the wave impedance in a free space. That is, the sensor substrate 100 can easily and efficiently absorb the radio wave noise of the resonance frequency fb (for example, 1.5 GHz band). The resonance frequency fa of the equivalent circuit LP1C is lower than the resonance frequency fb of the equivalent circuit LP2C. As a result, the sensor substrate 100 can easily absorb radio wave noise in a frequency band near the resonance frequency fa of the equivalent circuit LP1C and can easily absorb radio wave noise in a frequency band near the resonance frequency fb of the equivalent circuit LP2C.

In FIG. 3, a cross-sectional structure of the sensor substrate 100 in a plane parallel to an xz plane is disclosed, but as illustrated in FIGS. 5 and 6, in a plan view of the sensor substrate 100, the first unit cell CL1 and the second unit cell CL2 are disposed non-parallel (specifically, in an oblique direction) to a longitudinal direction of the dielectric substrate 14. More specifically, the first conductors EL1 constituting the first unit cells are arranged at equal intervals in the direction of the arrow W and the direction of the arrow V, which are inclined at 45 degrees from the x-axis and the y-axis with respect to the longitudinal direction (parallel to a y-axis direction in FIG. 5) of the rectangular first conductor layer (the dielectric substrate 14). Similarly, the second conductors EL2 constituting the second unit cells are arranged at equal intervals in the direction of the arrow W and the direction of the arrow V, which are inclined at 45 degrees from the x-axis and the y-axis with respect to the longitudinal direction (parallel to the y-axis direction in FIG. 5) of the rectangular second conductor layer (the dielectric substrate 13). In FIG. 5, illustration of the dielectric substrate 13 is omitted.

In a plan view of the sensor substrate 100 according to the present embodiment, the second conductor EL2 constituting one second unit cell is disposed so as to overlap a partial region of the first conductor EL1 constituting four first unit cells. As a result, the second unit cells can be efficiently and densely arranged with respect to the arrangement of the first unit cells, and the frequency band suitable for absorbing radio wave noise can be easily widened without increasing the size of the sensor substrate 100.

As illustrated in FIG. 6, in the sensor substrate 100 according to the present embodiment, each of the plurality of resistors (see FIG. 3) is connected to the first terminal rod of the first unit cell and the second terminal rod of the second unit cell. The place where the resistor is disposed can be considered as a measurement point of the incident radio wave to the sensor substrate 100. Therefore, by disposing the first unit cell CL1 and the second unit cell CL2 in the oblique direction with respect to the longitudinal direction of the dielectric substrate 14, the distance between the measurement points of the incident radio waves can be multiplied by √2. Here, when the length of one side of the square first conductor EL1 is a, the distance between the measurement points (that is, the distance between the two resistors disposed in parallel) is √2a (see FIG. 6). Accordingly, since one element (the second unit cell) of the periodic structure (the second EBG structure) can be made larger than one element (the first unit cell) of the same periodic structure (the first EBG structure), reception sensitivity can be improved as a whole in the frequency band to be operated (in other words, the frequency band to be absorbed).

In the sensor substrate 100 according to the present embodiment, the number of measurement points (in other words, the number of disposed resistors) is twice as large as that of a structure in a comparative example (see below), and the resolution of measurement related to absorption of radio wave noise can also be improved. Note that the structure in the comparative example referred to here is a configuration disclosed in Japanese Patent No. 5737672, and corresponds to a structure without the second unit cell of the sensor substrate 100 according to the present embodiment.

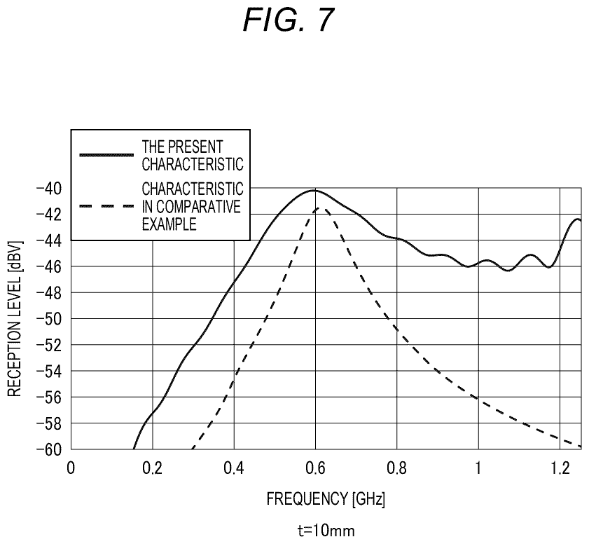

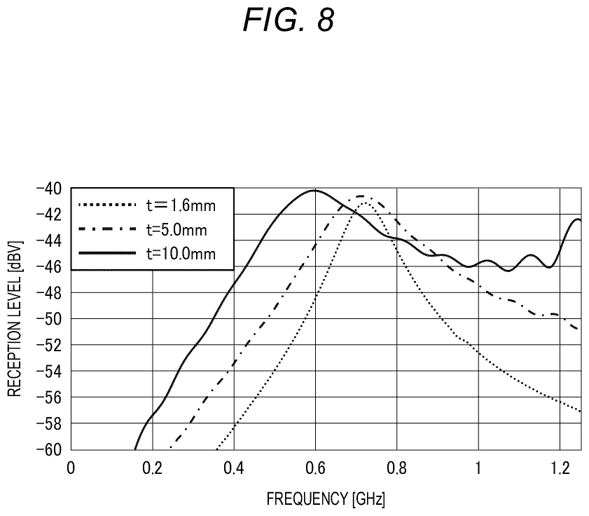

Next, frequency characteristics of the sensor substrate 100 according to the present embodiment will be described with reference to FIGS. 7 and 8. FIG. 7 is a diagram illustrating a reception level characteristic example in which the structure of the sensor substrate 100 according to the present embodiment and a structure of an antenna device according to the comparative example are compared. FIG. 8 is a diagram comparatively illustrating each reception level characteristic example when a distance t between the first conductor and the second conductor in the sensor substrate according to the present embodiment is variable. In FIGS. 7 and 8, a horizontal axis represents the frequency [GHz], and a vertical axis represents a reception level [dBV] of the radio wave noise incident on the sensor substrate 100.

In FIG. 7, the frequency characteristic of the radio wave noise absorbed by the sensor substrate 100 according to the present embodiment is indicated by a solid line (see the present characteristic), and the frequency characteristic of the radio wave noise absorbed by the structure in the comparative example (see above) is indicated by a broken line. The frequency characteristic indicated by the solid line in FIG. 7 is a simulation result calculated when the length (height) from the first conductor of the first unit cell to the second conductor of the second unit cell is 10 mm. Since the sensor substrate 100 according to the present embodiment has two equivalent circuits of the first EBG structure (see the equivalent circuit LP1C in FIG. 4) and the second EBG structure (see the equivalent circuit LP2C in FIG. 4), it is possible to widen the frequency band suitable for absorbing radio wave noise as compared with the structure in the comparative example. That is, as illustrated in FIG. 7, it can be seen that the reception level of the radio wave noise is relatively high (that is, the reception sensitivity is high) in a wide frequency band as compared with the structure in the comparative example.

In FIG. 8, the frequency characteristic when the length (height) t from the first conductor of the first unit cell to the second conductor of the second unit cell is 1.6 mm is indicated by a dotted line, the frequency characteristic when t is 5.0 mm is indicated by a one-dot chain line, and the frequency characteristic when t is 10.0 mm is indicated by a solid line. That is, in the sensor substrate 100 according to the present embodiment, the frequency characteristics when the thickness of the radio wave absorber 11 is changed are illustrated. As illustrated in FIG. 8, as t (in other words, the thickness of the radio wave absorber 11) decreases, the characteristic of the reception level of the radio wave noise is improved on a high frequency side where the frequency is higher. On the other hand, as t (in other words, the thickness of the radio wave absorber 11) increases, the characteristic of the reception level of the radio wave noise is improved on a low frequency side where the frequency is lower. This is based on the fact that a length of the loop (loop length) illustrated in FIG. 3 becomes longer as t (in other words, the thickness of the radio wave absorber 11) increases, and the resonance frequency based on each component of the inductance and the capacitance transitions to the low frequency side.

As described above, the antenna device (sensor substrate 100) according to the present embodiment includes the ground conductor GND1, the first conductor (for example, the first conductor EL12) disposed on the plane formed by the first conductor layer (the dielectric substrate 14) parallel to the ground conductor GND1, the first conductor rod (for example, the first conductor rod VC12) electrically connecting the first conductor and the ground conductor GND1, the plurality of first terminal rods (for example, the first terminal rods TB121 and TB122) extending from the first conductor to the back surface of the ground conductor GND1, the second conductor (for example, the second conductors EL21 and EL22) disposed above the first conductor and disposed on the plane formed by the second conductor layer (the dielectric substrate 13) parallel to the ground conductor GND1, and the plurality of second terminal rods (for example, the second terminal rods TB211, TB212, TB221, and TB222) extending from the second conductor to the back surface of the ground conductor GND1. As a result, since the antenna device has two types of EBG structures having different frequencies suitable for absorbing radio wave noise, it is possible to cope with a wider band of frequencies suitable for absorbing radio wave noise, to shorten a verification time for specifying the generation source of radio wave noise, and to improve the efficiency of noise countermeasures.

In the antenna device (the sensor substrate 100) according to the present embodiment, a plurality of first pairs of the first conductor (for example, the first conductor EL12), the first conductor rod (for example, the first conductor rod VC12), and the plurality of first terminal rods (for example, the first terminal rods TB121 and TB122) and a plurality of second pairs of the second conductor (for example, the second conductors EL21 and EL22) and the plurality of second terminal rods (for example, the second terminal rods TB211, TB212, TB221, and TB222) are periodically disposed with respect to the ground conductor GND1. Accordingly, the antenna device can periodically include the first EBG structure suitable for absorbing radio wave noise in the first frequency band (for example, the 800 MHz band) and the second EBG structure suitable for absorbing radio wave noise in the second frequency band (for example, the 1.5 GHz band), and can support shortening of the time for measurement of the frequency characteristics of radio wave noise of the device under test 50 with a wide area.

In the antenna device (sensor substrate 100) according to the present embodiment, a first equivalent circuit (the equivalent circuit LP1C) is formed by the ground conductor GND1, the first conductor (for example, the first conductor EL12), the first conductor rod (for example, the first conductor rod VC12), and the plurality of first terminal rods (for example, the first terminal rods TB121 and TB122). A second equivalent circuit (the equivalent circuit LP2C) is formed by the ground conductor GND1, the second conductor (for example, the second conductors EL21 and EL22), and the plurality of second terminal rods (for example, the second terminal rods TB211, TB212, TB221, and TB222). Accordingly, based on a magnitude relationship between the loop length of the loop LP1 that is the basis of the equivalent circuit LP1C and the loop length of the loop LP2 that is the basis of the equivalent circuit LP2C, the antenna device can easily absorb the radio wave noise in the equivalent circuit LP1C on the low frequency side having a longer wavelength than the equivalent circuit LP2C, and can easily absorb the radio wave noise in the equivalent circuit LP2C on the high frequency side having a shorter wavelength than the equivalent circuit LP1C.

In the antenna device (sensor substrate 100) according to the present embodiment, a first resonance frequency (for example, 800 MHz), which is the resonance frequency of the first equivalent circuit (the equivalent circuit LP1C), is lower than a second resonance frequency (for example, 1.5 GHz), which is the resonance frequency of the second equivalent circuit (the equivalent circuit LP2C). As a result, the antenna device can be used to analyze an EMC problem of an electronic device, for example, in a frequency band from the 800 MHz band to the 1.5 GHz band used in many applications.

In the antenna device (the sensor substrate 100) according to the present embodiment, each of the ground conductor GND1, the first conductor (for example, the first conductor EL12), and the second conductor (for example, the second conductors EL21 and EL22) is formed in a square (rectangular) shape. The first conductor and the second conductor are arranged such that a side direction (for example, the direction of the arrow W or the direction of the arrow V in FIG. 5) connecting end points of the first conductors having the shortest adjacent distance and a side direction connecting end points of the second conductors having the shortest adjacent distance are oblique to the longitudinal direction of the ground conductor GND1, respectively. As a result, in the antenna device, one element (the second unit cell) of the periodic structure (the second EBG structure) can be made larger than one element (the first unit cell) of the same periodic structure (the first EBG structure) (see FIG. 6), so that antenna characteristics of a longer wavelength (in other words, on a low frequency side) can be improved.

In the antenna device (the sensor substrate 100) according to the present embodiment, the length in the thickness direction from the ground conductor GND1 to the first conductor (for example, the first conductor EL12) is shorter than the length in the thickness direction from the first conductor to the second conductor (for example, the second conductors EL21 and EL22). Accordingly, the antenna device can secure a wide range from a frequency suitable for absorbing radio wave noise by the first EBG structure to a frequency suitable for absorbing radio wave noise by the second EBG structure.

Although the embodiment has been described above with reference to the accompanying drawings, the present disclosure is not limited thereto. It is apparent to those skilled in the art that various modifications, corrections, substitutions, additions, deletions, and equivalents can be conceived within the scope described in the claims, and it is understood that such modifications, corrections, substitutions, additions, deletions, and equivalents also fall within the technical scope of the present disclosure. In addition, components in the embodiment described above may be combined freely in a range without deviating from the spirit of the invention.

The present application is based on a Japanese Patent Application (Japanese Patent Application No. 2022-183563) filed on Nov. 16, 2022, and the contents thereof are incorporated herein by reference.

### INDUSTRIAL APPLICABILITY

The present disclosure is useful as an electric field detection method and device that can cope with a wider frequency band suitable for absorbing radio wave noise and support shortening of a time required for verification for specifying a radio wave noise generation source.

### REFERENCE SIGNS LIST

11 radio wave absorber
12 signal output unit
13 dielectric substrate
14 dielectric substrate
50 device under test
100 sensor substrate
200 display PC
1000 electric field detection device
EL11, EL12, EL13 first conductor
EL21, EL22 second conductor
GND1 ground conductor
LP1, LP2 loop
RW1 radio wave source
SW1, SW2, SW3, SW4, SW5 RF switch element
TB111, TB112, TB121, TB122, TB131, TB132 first terminal rod
TB211, TB212, TB221, TB222 second terminal rod
VC11, VC12, VC13 first conductor rod

1. An antenna device comprising:
a ground conductor;
a first conductor disposed on a plane formed by a first conductor layer parallel to the ground conductor;
a first conductor rod electrically connecting the first conductor and the ground conductor;
a plurality of first terminal rods extending from the first conductor to a back surface of the ground conductor;
a second conductor disposed above the first conductor and disposed on a plane formed by a second conductor layer parallel to the ground conductor; and
a plurality of second terminal rods extending from the second conductor to the back surface of the ground conductor.

2. The antenna device according to claim 1, wherein
a plurality of first pairs of the first conductor, the first conductor rod, and the plurality of first terminal rods and a plurality of second pairs of the second conductor and the plurality of second terminal rods are periodically disposed with respect to the ground conductor.

3. The antenna device according to claim 1, wherein
a first equivalent circuit is formed by the ground conductor, the first conductor, the first conductor rod, and the plurality of first terminal rods, and
a second equivalent circuit is formed by the ground conductor, the second conductor, and the plurality of second terminal rods.

4. The antenna device according to claim 3, wherein
a first resonance frequency, which is a resonance frequency of the first equivalent circuit, is lower than a second resonance frequency, which is a resonance frequency of the second equivalent circuit.

5. The antenna device according to claim 1, wherein
each of the ground conductor, the first conductor, and the second conductor is formed in a square shape, and
the first conductor and the second conductor are arranged such that a side direction connecting end points of the first conductors having shortest adjacent distances and a side direction connecting end points of the second conductors having shortest adjacent distances are oblique to a longitudinal direction of the ground conductor, respectively.

6. The antenna device according to claim 1, wherein
a length in a thickness direction from the ground conductor to the first conductor is shorter than a length in the thickness direction from the first conductor to the second conductor.
